(19) United States
(12) Patent Application Publication
(10) Pub. No.: US 2015/0247234 A1
(43) Pub. Date: Sep. 3, 2015

(54) METHOD FOR RELOADING AN EVAPORATION CELL

(71) Applicant: RIBER, BEZONS CEDEX (FR)

(72) Inventors: David ESTEVE, BOUGIVAL (FR); Franck STEMMELEN, VAUREAL (FR); Christophe DE OLIVEIRA, CHATOU (FR)

(21) Appl. No.: 14/635,296

(22) Filed: Mar. 2, 2015

(30) Foreign Application Priority Data
Mar. 3, 2014 (FR) 14 51712

(51) Int. Cl. C23C 14/24; C23C 14/02

(52) U.S. Cl. CPC C23C 14/243; C23C 14/02

(57) ABSTRACT

A method for reloading an evaporation cell intended to evaporate a material onto a substrate placed in a vacuum deposition chamber, a first crucible containing the material to be evaporated being engaged with an evaporation chamber of the cell, and elements for placing the first crucible in conditions of evaporation to generate a flow of vapor of the material, the method including: loading a second crucible containing the material to be evaporated in a loading chamber previously isolated from the adjacent evaporation chamber, the pressure in the loading chamber being then substantially higher than that in the vacuum deposition chamber; confining the pressure inside the loading chamber to a level comparable to that of the evaporation chamber during the evaporation of the first crucible; transferring the first crucible to the loading chamber, engaging the second crucible with the evaporation chamber, and placing the second crucible in conditions of evaporation.

### FIELD OF THE INVENTION

The invention relates to the field of evaporation and vacuum deposition of materials onto a substrate.

The invention more particularly relates to a method for reloading an evaporation cell intended to evaporate a material, in order for the latter to be deposited onto a substrate placed in a vacuum deposition chamber.

### BACKGROUND OF THE INVENTION

A vacuum deposition apparatus allows to deposit a material, such as a semi-conductor material or compound (for example: silicon, gallium arsenide, indium phosphide, etc.), an inorganic material (for example: selenium, antimony, phosphorus), or an organic material (for example: tris(8-hydroxyquinoline)aluminum (III) or Alq3, . . . ), evaporated within an evaporation chamber, onto a substrate placed in a deposition chamber maintained under vacuum.

Such an apparatus includes in particular an evaporation cell intended to evaporate the material, a first crucible containing the material to be evaporated being then engaged with the evaporation chamber of said evaporation cell, evaporation means being provided to place this first crucible in conditions of evaporation to generate a flow of vapor of the material through an outlet of the evaporation chamber, the outlet being connected to an injector for the injection of the vapor into the vacuum deposition chamber.

To ensure a quasi-continuous production, it is possible to exploit an evaporation cell using a high capacity crucible containing a high quantity of material to be evaporated, so that it is then possible to deposit the material onto a great number of successive substrates.

However, when using high capacity crucibles, it is necessary, for the replacement thereof, to wait for them to be cold before being able to reload the evaporation cell, so as not to disturb the thermal stability of the evaporation chamber by the removal of a hot crucible and the introduction of a cold crucible into the evaporation chamber.

Hence, the reloading of the evaporation cell leads to a long interruption of the production, as it is not possible to prepare a new crucible for the evaporation thereof before having been able to disengage the first crucible from the evaporation cell.

This interruption of production, which may be of a few hours to several days as a function of the size of the crucibles, reduces the production rate and increases the cost of the operation of material deposition onto the substrate.

To ensure a continuous production, a vacuum deposition apparatus as described in the document WO 2006/001205, including two separated evaporation cells, could also be used.

Nevertheless, the integration of several evaporation cells in a same vacuum deposition apparatus is complex and expensive.

### SUMMARY OF THE INVENTION

To remedy the above-mentioned drawback of the state of the art, the present invention proposes a method for reloading an evaporation cell allowing to reduce, or even to cancel, the downtimes in a deposition method implemented by a vacuum deposition apparatus using this evaporation cell.

For that purpose, the invention relates to a method for reloading an evaporation cell intended to evaporate a material, in order for the later to be deposited onto a substrate placed in a deposition chamber maintained under vacuum, a first crucible containing said material to be evaporated being engaged with an evaporation chamber of said evaporation cell, evaporation means being provided to place said first crucible in conditions of evaporation to generate a flow of vapor of the material through an outlet of said evaporation chamber, said outlet being connected to an injector for the injection of said vapor into said vacuum deposition chamber, said reloading method including:
a step of loading a second crucible containing the material to be evaporated into a loading chamber previously isolated from said adjacent evaporation chamber, the pressure inside said loading chamber being then substantially higher than that inside the vacuum deposition chamber,
after said introduction step, a step of confining said loading chamber intended to bring back the pressure inside said loading chamber to a level comparable to that of said evaporation chamber during the evaporation of said first crucible,
after said confinement step, a step of disengaging said first crucible from said evaporation chamber, during which said first crucible is transferred from said evaporation chamber to said loading chamber,
after said step of disengaging the first crucible, a step of engaging said second crucible with said evaporation chamber, and
after said step of engaging said second crucible, a step of placing said second crucible in conditions of evaporation to generate a flow of vapor of the material through said outlet of the evaporation chamber.

According to the invention, during said step of engaging said second crucible, said loading chamber is isolated from said evaporation chamber and from said vacuum deposition chamber.

Thanks to the isolation obtained by the engagement of the first crucible with the evaporation chamber, the reloading method according to the invention allows with a single evaporation chamber and a single loading chamber to perform a rapid change of crucible with no long interruption of the deposition method.

Indeed, thanks to said loading chamber previously isolated from said evaporation chamber, it is possible, before the step of disengaging the first crucible, to prepare the second crucible while the first crucible is under evaporation in the evaporation cell.

The loading method is particularly adapted to the case where small volume crucibles are used, requiring a frequent replacement of crucible.

Besides, other advantageous and non-limitative characteristics of the method according to the invention are the following:
during said step of loading said second crucible, a trap door of said loading chamber is open, and said second crucible is introduced into said loading chamber, from the outside of said evaporation cell, through said trap door;
during said confinement step, said trap door is tightly closed with respect to the outside of said evaporation cell, and a pumping is performed inside said loading chamber;
during said step of disengaging the first crucible, said first crucible is removed from said evaporation chamber by being passed through an insertion opening placing said loading chamber and said evaporation chamber in communication with each other, and during said step of engaging said second crucible, said second crucible is inserted into said evaporation chamber by being passed through said insertion opening, and said insertion opening is tightly shut to isolate said loading chamber from said evaporation chamber;
said loading method includes, before said step of engaging said second crucible with said evaporation chamber, a step of preparing said second crucible in said loading chamber, intended to reduce the duration of said step of placing said second crucible in conditions of evaporation;
said preparation step comprises a step of pre-heating said second crucible in said loading chamber, up to a predetermined pre-heating temperature.

### BRIEF DESCRIPTION OF THE DRAWINGS

Embodiments of the invention will be described in detail with reference to the drawings, in which:

FIG. 1 is a sectional schematic overall view in a vertical plane of a vacuum deposition apparatus according to an embodiment of the invention including an evaporation cell and a vacuum deposition chamber;

FIG. 2A is a sectional schematic view in a vertical plane of a first example of evaporation cell including an evaporation chamber with which a first full crucible is engaged, and an adjacent loading chamber comprising an empty crucible;

FIG. 2B is a detail view of the zone II of FIG. 2A;

FIG. 3 is a sectional schematic view in a vertical plane of the evaporation cell of FIG. 2A, at the time of initial loading of the loading chamber with a second full crucible;

FIG. 4 is a sectional schematic view in a vertical plane of the evaporation cell of FIG. 2A, during the evaporation of the first crucible;

FIG. 5 is a sectional schematic view in a vertical plane of the evaporation cell of FIG. 2A, before the disengagement of the first empty crucible from the evaporation chamber;

FIG. 6 is a sectional schematic view in a vertical plane of the evaporation cell of FIG. 2A, after the disengagement of the first empty crucible from the evaporation chamber;

FIG. 7 is a sectional schematic view in a vertical plane of the evaporation cell of FIG. 2A, before the engagement of the second full crucible with the evaporation chamber;

FIG. 8 is a sectional schematic view in a vertical plane of the evaporation cell of FIG. 2A, after the engagement of the second crucible with the evaporation chamber, during the step of conditioning the second crucible;

FIG. 9A is a sectional schematic view in a vertical plane of a second example of evaporation cell;

FIG. 9B is a detail view of the zone IX of FIG. 9A, showing the means for shutting an insertion opening between the evaporation chamber and the loading chamber of the evaporation cell of FIG. 9A;

FIG. 10 is a schematic view of a third example of evaporation cell including a tight valve between the evaporation chamber and the injector;

FIG. 11 is a schematic view of a variant of the third example of the evaporation cell of FIG. 10 in which the outer enclosure of the evaporation chamber is isolated from the vacuum deposition chamber;

FIG. 12 is a schematic view of a fourth example of evaporation cell including two distinct evaporation chambers.

### DETAILED DESCRIPTION OF THE INVENTION

In the following disclosure, the terms “top” and “bottom” will be used with reference to the vertical, in relation to the room in which the vacuum deposition apparatus is installed, the top referring to the side directed towards the ceiling of the room and the bottom referring to the side directed towards the floor. Likewise, the terms “lower” and “upper” will refer to the sides directed towards the bottom and the top, respectively.

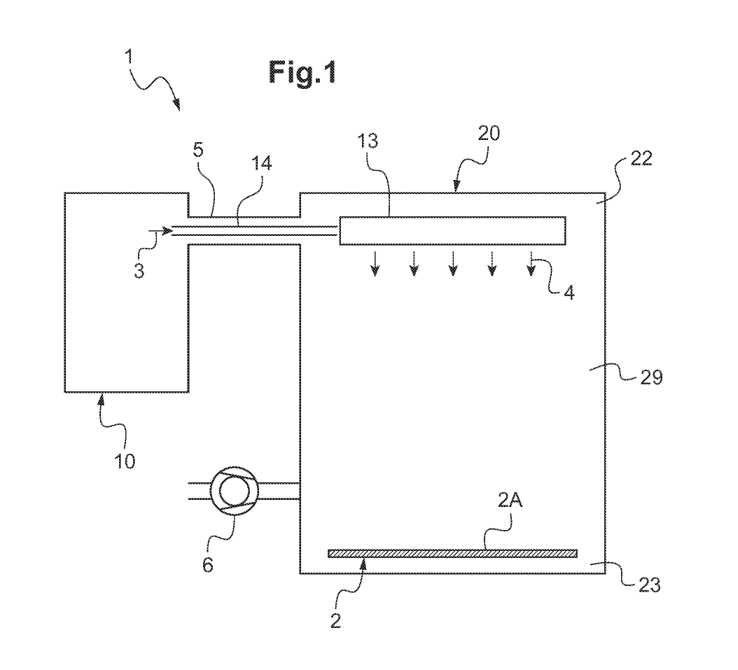

FIG. 1 shows a sectional schematic overall view in a vertical plane of a vacuum deposition apparatus 1, which includes, on the one hand, an evaporation cell 10, and on the other hand, a vacuum deposition chamber 20.

Generally, the evaporation cell 10 of the vacuum deposition apparatus 1 is intended to evaporate a material, in order for the latter to be deposited onto a substrate 2 placed in the vacuum deposition chamber 20, here in a bottom part 23 of the latter.

It will be seen hereinafter that the evaporation cell 10 is adapted to generate an upstream flow of vapor 3 of said material, which upstream flow of vapor 3 is transported by an injection duct 14 from the evaporation cell 10 to an injector 13 located in the top part 22 of the vacuum deposition chamber 20.

The evaporation cell 10 and the vacuum deposition chamber 20 are connected to each other by a tubular connector 5 passed through by the injection duct 14.

The injector 13 of the evaporation cell 10 injects the vapor of material transported by the injection duct 14 into the vacuum deposition chamber 20 along a downstream flow of vapor 4 directed downward towards the substrate 2, so that the material is deposited onto an upper face 2A of the substrate 2 directed towards the injector 13.

The injector 13 is adapted to optimize the characteristics of the downstream flow of vapor 4 directed towards the substrate 2, for example the flow rate or the spatial distribution thereof, so that the layer of material deposited on the upper face 2A of the substrate 2 has the required properties, such as the thickness, the state of surface, the conductivity, etc. . . . , as a function of the intended application.

Inside the injector 13 are provided specific heating means (not shown), intended to avoid the condensation of the vapors of material inside the injector 13, which could compromise the good operation thereof.

In order to make and maintain the vacuum inside the vacuum deposition chamber 20, the vacuum deposition apparatus 1 includes pumping means 6 connected to the vacuum deposition chamber 20, whose pumping capacities are adjusted as a function of the inner volume 29 of the vacuum deposition chamber 20.

These pumping means 6 herein comprise a turbo-molecular pump or a cryogenic pump, which lowers the level of pressure inside the vacuum deposition chamber 20 down to 10⁻³ to 10⁻⁸ Torr.

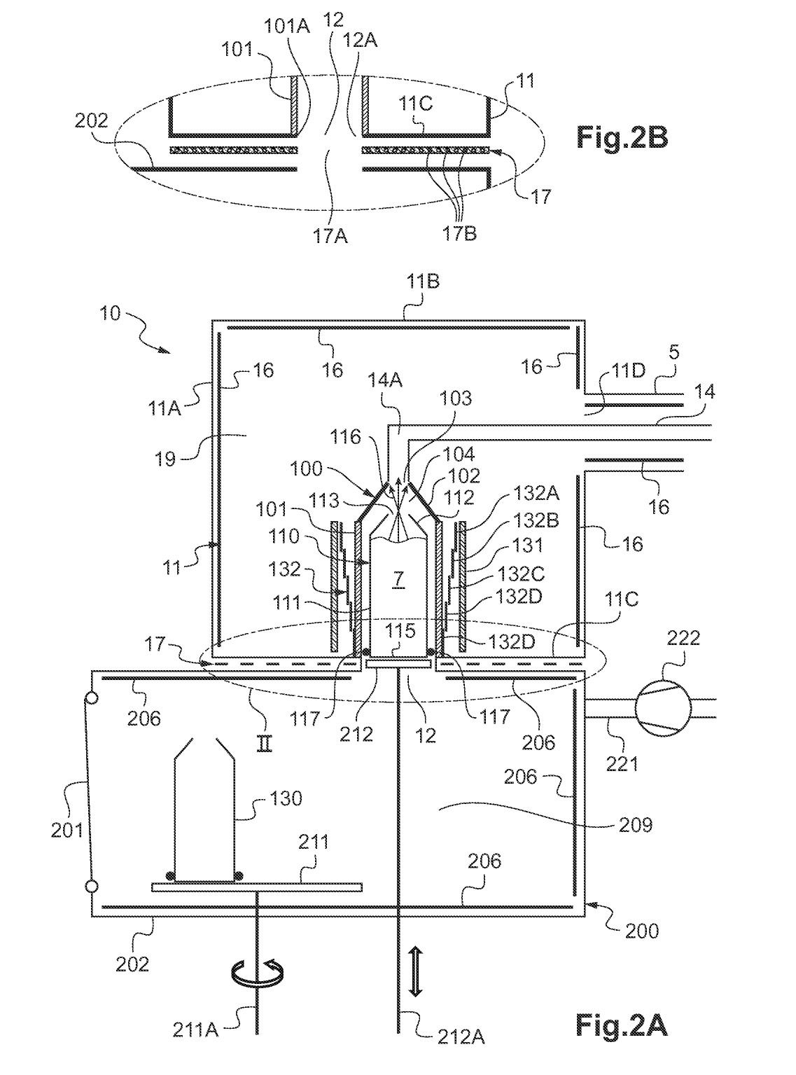

A first example of evaporation cell 10 intended to produce a downstream flow of vapor 3 towards the injector 13 will now be described with reference to FIGS. 2 to 9B. A loading method according to the invention allowing to exploit quasi-continuously this evaporation cell 10, i.e. by limiting the downtimes of the production of the downstream flow of vapor 3, will also be described.

As shown in FIG. 2A, the evaporation cell 10 of the vacuum deposition apparatus 1 first includes an outer enclosure 11, herein of generally cylindrical shape, comprising a lateral wall 11A, an upper wall 11B (or “roof”), and a lower wall 11C (or “bottom”).

On the inner faces of the lateral wall 11A and of the upper wall 11B of the outer enclosure 11, and also of the tubular connector 5, are provided heating elements, for example heating resistances 16, intended to heat substantially homogeneously the inner volume 19 of the outer enclosure 11, in particular the injection duct 14, so as to avoid that the vapors of material are condensed on the cold parts of the evaporation cell 10.

On the outer faces of the lateral wall 11A, of the upper wall 11B, and also of the tubular connector 5, are provided cooling elements (not shown), for example cold water coils, so that the outer enclosure 11 of the evaporation cell 10 is cold to the touch from the outside.

Between the heating elements 16 and the cooling elements is inserted a radiative shield, for example made as a refractory material, so that the heating and the cooling are each independently efficient.

The lateral wall 11A comprises an opening 11D from which the tubular connector 5 extends outwardly for the connection of the evaporation cell 10 with the vacuum deposition chamber 20 of the vacuum deposition apparatus 1.

In this configuration (common to FIGS. 1 to 10 and 12), the outer enclosure 11 and the vacuum deposition chamber 20 are in communication with each other and share the same vacuum, so that when the vacuum is made inside the vacuum deposition chamber 20, it is also made inside the outer enclosure 11 of the evaporation cell 10. The level of pressure in the outer enclosure 11 is hence equal to that in the vacuum deposition chamber 20.

As a variant, as shown in FIG. 11, a tight weld 18 can be provided between the tubular connector 5 and the injection duct 14 of the evaporation cell 10, so that the outer enclosure 11 of the evaporation cell 10 does not share the same vacuum as the vacuum deposition chamber 20. In this case, the evaporation cell 10 then comprises an enclosure pump 19A that is dedicated thereto and that is intended to pump the inner volume 19 of the outer enclosure 11 to make the pressure fall down to a level of the order of 10⁻² to 10⁻³ Torr.

As can be seen in FIGS. 2A and 2B, an opening, called hereinafter insertion opening 12, is cut in the lower wall 11C of the outer enclosure 11.

This insertion opening 12 has an inner edge 12A, which is herein circular in shape, above which extends, towards the inside of the outer enclosure 11, an evaporation chamber 100 of the evaporation cell 10.

The evaporation chamber 100 is delimited by a tight wall comprising, on the one hand, a cylindrical body 101 coaxial to the insertion opening 12, and on the other hand, a truncated cone neck 102 continuing the body 101, up to an outlet 103 of the evaporation chamber 100.

This body 101 of the evaporation chamber 100 has a lower edge 101A, which extends with no interruption along the inner edge 12A of the insertion opening 12. The lower edge 101A is hermetically fixed to the lower wall 11C of the outer enclosure 11 of the evaporation cell 10, so that the inner volume 19 of the outer enclosure 11 of the evaporation cell 10 does not communicate with the inner volume 104 of the evaporation chamber 10.

The outlet 103 of the evaporation chamber 100 is tightly connected to the injection duct 14 of the evaporation cell 10, herein forming a bend 14A at said outlet 103. The tight connection can be made, for example, by means of a welding.

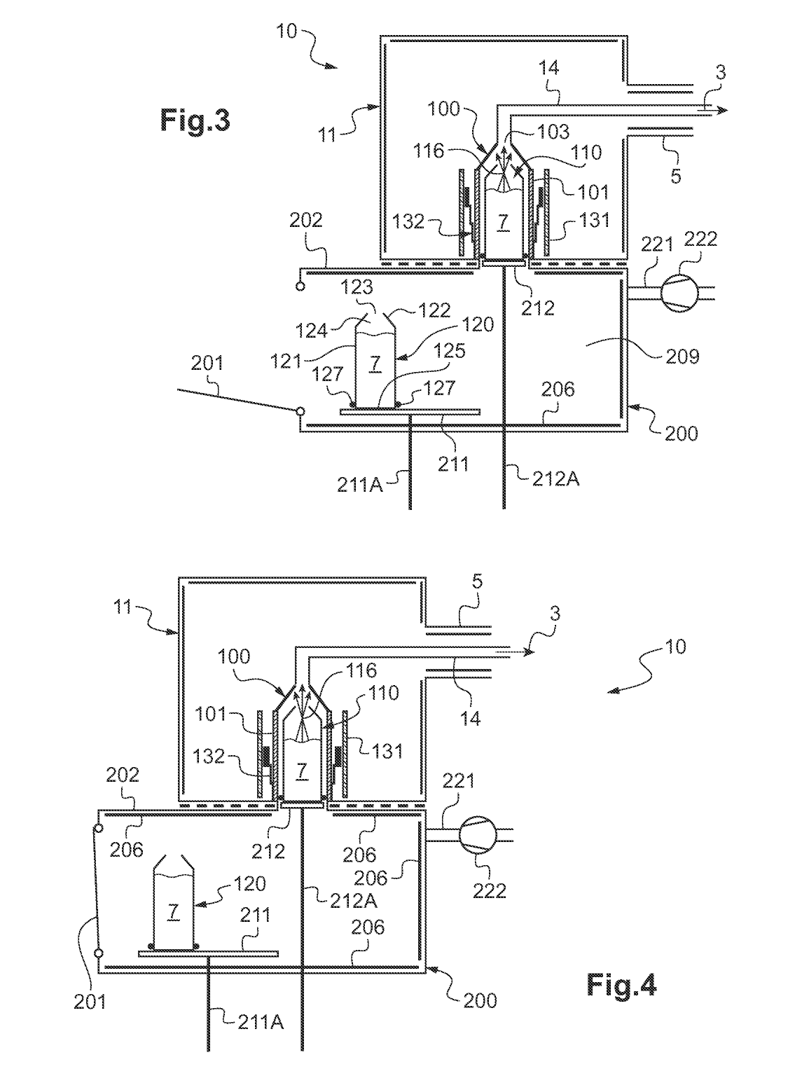

The evaporation chamber 100 of the evaporation cell 10 is intended to receive a crucible, such as the first crucible 110 (see FIG. 2A) and the second crucible 120 (see FIG. 3). These crucibles 110, 120 have adapted shapes and sizes so as to be able to be received in the evaporation chamber 100.

Advantageously, the crucibles 110, 120 have a low volume capacity, lower than 1 litre (L), preferably lower than 0.5 L, for example equal to 0.33 L.

They have generally the shape of a bottle and comprise a lateral wall 111, 121 that is closed downward by a bottom 115, 125 and that narrows upward into a neck 112, 122 delimiting an opening 113, 123 of the crucible 110, 120.

The crucibles 110, 120 are preferably made single part from a material having a good transparency to infrareds and a resistance to high temperatures. The crucibles 110, 120 may, for example, be made of a ceramic material such as the pyrolytic boron nitride or PBN, or a material of the vitreous type such as quartz.

They are intended to be filled with the material 7 to be evaporated, wherein the material 7 can be in liquid form, powder form, or even in an ingot form.

When a crucible (case of the first crucible 110 in FIG. 3, case of the second crucible 120 in FIG. 8) is engaged with the evaporation chamber, i.e. when it is received inside the inner volume 104 of the evaporation chamber 100, the lateral wall 111, 121 thereof is then opposite the body 101 of the evaporation chamber 100.

In order to place in conditions of evaporation a crucible 110, 120 engaged with the evaporation chamber 100, the evaporation cell also includes evaporation means arranged at the periphery of the evaporation chamber 100 receiving said crucible 110, 120.

In all the examples described in FIGS. 2 to 12, these evaporation means first comprise electric resistances 131 surrounding the evaporation chamber 100 and extending from the bottom 11C of the outer enclosure 11, substantially parallel to the body 101 of the evaporation chamber 100, up to the neck 102 of the latter.

These electric resistances 131 are power supplied and heated at high temperature so that they radiate heat, essentially as infrareds.

As a variant, the evaporation means may comprise infrared lamps placed directly in the inner volume of the evaporation chamber, against the body of the latter, so as to irradiate directly the crucible engaged in the evaporation chamber.

The evaporation means also comprise a thermal shield 132 located inside the outer enclosure 11 and interposed between the body 101 of the evaporation chamber 100 and the electric resistances 131.

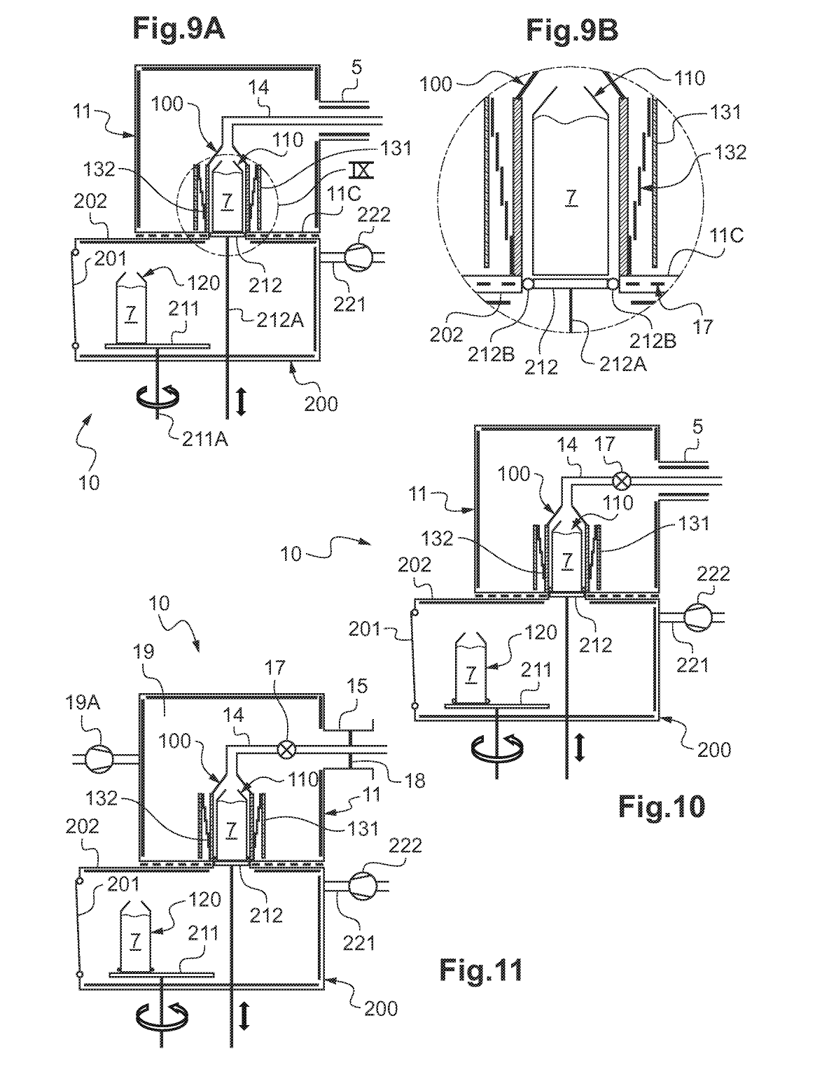

As well shown in FIG. 9B, this thermal shield 132 is of “telescopic” type and herein includes five mobile elements 132A, 132B, 132C, 132D, 132E, cylindrical and coaxial to each other, which may nest into each other so that the height of the thermal shield 132 can be adjusted at will.

For example, FIG. 2A shows the thermal shield 132 in its greatest height, when all the mobile elements 132A, 132B, 132C, 132D, 132E are extended. FIG. 6 shows the thermal shield 132, 230 when all the mobile elements 132A, 132B, 132C, 132D, 132E are nested into each other.

The mobile elements 132A, 132B, 132C, 132D, 132E are herein formed of cylinders made of the same material, for example a metal material, such as steel or aluminum.

As a variant, the mobile elements may for example consist in cylinders made of quartz, glass or silica, whose external face directed towards the electric resistances is coated with a layer reflecting the thermal radiation emitted by these electric resistances, for example a metal layer, such as a layer of silver, aluminum or gold.

The evaporation means moreover include operation means allowing to slide the mobile elements 132A, 132B, 132C, 132D, 132E with respect to each other to adjust the height of the thermal shield 132.

Although in FIGS. 2 to 12 the mobile elements 132A, 132B, 132C, 132D, 132E are five in number and have all the same height, it can be considered as a variant that the evaporation means comprise more or less mobile elements and that these latter be of different heights. This can be advantageous in particular to adapt the height of the thermal shield to the height of the evaporation chamber and to adjust this height with more or less accuracy.

The evaporation means finally include herein the cylindrical body 101 of the evaporation chamber 100, which has a transparent wall that is chosen so as to transmit the infrared radiation emitted by the electric resistances 131.

In the conditions of pressure inside the outer enclosure 11, the heat exchanges between the electric resistances 131 and the body 111, 121 of a crucible 110, 120 engaged with the evaporation chamber 100 essentially occur by radiation, because the convection exchanges are strongly limited due to the vacuum inside the outer enclosure 11.

The transparent wall may for example be formed of a hollow cylinder made of quartz, glass or silica, possibly coated with a layer improving the infrared transmission of the transparent wall.

The thermal shield 132, arranged between the electric resistances 131 and this transparent wall of the body 101 of the evaporation chamber 100, will hence act as a mirror for the infrared light radiated by the electric resistances 131 towards the body 111, 121 of a crucible 110, 120 located in the evaporation chamber 100.

Hence, thanks to the thermal shield 132, it is possible to uncover all or part of the electric resistances 131, so that only the fraction of material 7 contained in the upper part 114, 124 of the crucibles 110, 120, be subjected to the radiation emitted by the electric resistances and be heated, as a function of the pressure in the evaporation chamber, up to a sufficient heating temperature to allow the evaporation thereof.

Moreover, thanks to the operation means sliding the mobile elements 132A, 132B, 132C, 132D, 132E, it is possible to finely adjust the height of the thermal shield 132 to adjust in real time the flow of vapor 116, 126 (see FIGS. 4 and 8) through openings 113, 123 of the crucibles 110, 120.

In particular, it is possible to obtain conditions of evaporation in which the flow of vapor 116, 126 remains substantially constant all along the evaporation of the material 7 contained in the crucibles 110, 120. This reveals to be particularly interesting for the deposition of a uniform layer on the substrate 2 placed in the vacuum deposition chamber 20.

The flow of vapor 116, 126 of the material 7 generated thanks to the evaporation means 131, 132, 101 heating the crucibles 110, 120 located in the evaporation chamber 100 then passes through the outlet 103 of the evaporation chamber 100 and is then transported up to the injector 13 along the injection duct 14 of the evaporation cell 10, such injector 13, as seen hereinabove, generating the upstream flow of vapor 4 towards the substrate 2 placed in the vacuum deposition chamber 20.

As shown in FIGS. 2 to 12, the evaporation cell 10 also includes a loading chamber 200 adjacent to the evaporation chamber 100 and located herein under the outer enclosure 11 of the evaporation cell 10.

This loading chamber 200 is delimited by a confining enclosure 202 and includes a trap door 201 allowing:
in the open position, to place the inner volume 209 of the loading chamber 200 in communication with the outside of the evaporation cell 10, for example with the room in which the vacuum deposition apparatus 1 is stored, and
in the closed position, to isolate the inner volume 209 of the loading chamber 200 from the outside of the evaporation cell 10.

Advantageously, it can be provided to adjoin to the loading chamber, upstream the latter, a lock chamber placed under neutral atmosphere, for example with an inert gas at a pressure close to the atmosphere. This lock chamber then allows to fill crucibles intended to be introduced into the loading chamber with materials that are oxidized by free air, such as the organic materials, for example.

As for the outer enclosure 11 of the evaporation cell 10, it is provided, on the inner faces of the confining enclosure 202, heating elements, for example heating resistances 206, intended to heat substantially homogeneously the inner volume 209 of the loading enclosure, and in particular the different elements that it may contain, such as the crucibles 110, 120.

The confining enclosure 202 of the loading chamber 200 comprises on its upper wall an opening located opposite the insertion opening 12 carrying the evaporation chamber 100, so that the loading chamber 200 is in communication with the evaporation chamber 100 through this insertion opening 12 when the latter is not shut.

The loading chamber 200 moreover includes an additional pump 222 connected to the confining enclosure 202 via a pumping duct 221 to vacuum said loading chamber 200, for example when the latter has been reaerated through the opening of the trap door 201.

In the loading chamber 200 are moreover provided crucible loading and unloading means 110, 120, herein a carrousel and piston system.

More precisely, the loading chamber 200 firstly includes a piston 212A at the upper end of which is fixed a plate 212 intended to receive the first crucible 110 or the second crucible 120.

The piston 212A is mobile in vertical translation, so that the plate 211 can go up and down along the axis of the piston 212A, between:
a “bottom” position (cases of FIGS. 2, 6 and 7) in which the plate 212 is close to the lower wall of the confining enclosure 202, and
a “top” position (case of FIGS. 3, 4, 5, 8, 10, 11 and 12) in which the plate 212 is located at the insertion opening 12 of the evaporation cell 10.

The bottom position allows the loading or unloading of the plate 212 with a crucible 110, 120.

Once the crucible 110, 120 in place on the plate 212, the latter can go up vertically thanks to the piston 212A and hence engage the crucible 110, 120 with the evaporation chamber 100, by passing through the insertion opening 12 of the evaporation cell 10.

The loading chamber 200 also includes a carrousel 211 mounted on an axis of rotation 211A allowing to drive the carrousel 211 into rotation.

This carrousel 211 is intended to receive the crucibles 110, 120 for the loading and unloading thereof onto and from the plate 212.

The system of carrousel 211 and plate 212 is particularly advantageous because it offers a reduced size for a given number of crucibles. Hence, the size of the loading chamber 200 and the pumping capacities of the additional pump 222 connected to the loading chamber 200 can be limited.

As shown in FIG. 2B, thermal shielding means are provided, which are interposed between the outer enclosure 11 of the evaporation cell 10 and the loading chamber 200.

More precisely, these thermal shielding means herein comprise a connection flange 17 allowing the attachment of the lower wall 11C of the outer enclosure 11 to the upper wall of the loading chamber 200. This connection flange 17 has a connection opening 17A coaxial to the insertion opening 12 and includes a coil network 17B in which circulates a cooling liquid (water, nitrogen, etc. . . . ).

This connection flange 17 allows in particular to thermally isolate the evaporation chamber 100 from the loading chamber 200 and to avoid that the heat emitted by the different heating means 16 of the evaporation cell 10 has a disturbing effect on a crucible 110, 120 placed in the loading chamber 200, and vice versa so as not to the disturb the thermal gradient in the crucible 110, 120 during evaporation.

That way, it is possible to remove the first crucible 110 from the evaporation chamber 100, “under hot conditions”, when it is hot, without waiting for the cooling thereof. The second crucible 120 can then be introduced into the evaporation chamber 100 as soon as the first crucible 110 has been removed, and the evaporation can be resumed as soon as this second crucible 120 is at temperature.

Moreover, thanks to the thermal shielding means 17, it is possible to load the second crucible 120 into the loading chamber 200 while the first crucible 110 is under evaporation, and this despite the heat emitted by the evaporation means 131, 132 that heat the first crucible 110. This heat emitted has no noticeable and harmful thermal effect on the second crucible 120 located in the loading chamber 200. In particular, the temperature of the material 120 to be evaporated present in the crucible 120 remains lower than the temperature of evaporation of the material 7.

To implement the loading method according to the invention, there are finally means for shutting the insertion opening 12 of the evaporation cell 10, which are advantageously implemented at the time of engagement of a crucible 110, 120 with the evaporation chamber.

In the exemplary embodiments shown in FIGS. 2 to 8 and 10 to 12, these shutting means comprise an O-ring joint 117, 127 fixed along the lateral wall 111, 212 of the crucibles 110, 120, in the lower part of the latter, close to the bottom 115, 125 of the crucible 110, 120.

The outer diameter of the joint 117, 127 is chosen so that, when a crucible 110, 120 is inserted into the evaporation chamber 100 using the piston 212A and the plate 121 of the loading chamber 200, the joint 117, 127 comes into contact with the body 101 of the evaporation chamber 100.

That way, when a crucible 110, 120 is loaded inside the evaporation chamber 100, the joint 117, 127 allows to ensure the tightness of the evaporation chamber 100 with respect to the loading chamber 200.

In other words, thanks to the joint 117, 127 provided on the crucibles 110, 120, it is then possible at the time of engagement of a crucible 110, 120 with the evaporation chamber 100, to isolate the loading chamber 200 with respect to the evaporation chamber 100.

In another exemplary embodiment shown in FIGS. 9A and 9B, the shutting means comprise a joint 212B attached to the peripheral edge of the plate 212.

In the same way as hereinabove, the outer diameter of the joint 212B is chosen so that, when a crucible (the first crucible 110 in the case of FIGS. 9A and 9B) is inserted into the evaporation chamber 100 using the piston 212A and the plate 212 of the loading chamber 200, the joint 212B comes into contact with the body 101 of the evaporation chamber 100 so as to tightly close the insertion opening 12 of the evaporation cell 10.

As shown in FIG. 10, it can also be provided a valve 17 placed on the injection duct 14 of the evaporation cell 10.

Advantageously, this valve 17 may for example be a tight “all or nothing” valve with two open and closed positions, which allows, in the closed position, when the evaporation chamber 100 is empty, to avoid that the flow of vapor comes back towards the evaporation chamber 100 and goes towards the loading chamber 200, which is colder, to condensate on the lower walls of the loading enclosure 202.

As a variant, two valves could be provided, placed in series on the injection duct: a first tight valve of the “all or nothing” type and a second regulation valve, downstream the first tight valve.

Although the flow rate of the flow of vapor at the outlet of the evaporation chamber is adjusted thanks to the evaporation means, this regulation valve may also allow to adjust more finely the flow rate of vapor of the material 7.

Preferably, these valves are placed in the outer enclosure 11 of the evaporation cell 10 so as to be heated during the use thereof in order to avoid the problems of condensation in these valves.

An example of implementation of the method for loading the evaporation cell 10 of the vacuum deposition apparatus 1 will now be described, with reference to FIGS. 2 to 8.

The following description will allow to understand the advantages of such a loading method to reduce the downtimes of the vacuum deposition apparatus 1.

It will be considered herein, as shown in FIG. 2A, that the vacuum deposition apparatus 1 is in operation and that:
a first crucible 110 is engaged with the evaporation chamber 100 of the evaporation cell 10 and heated by the evaporation means 131, 132, so as to generate a flow of vapor 116 through the outlet 103 of the evaporation chamber 100, and
a previous crucible 130, whose content has already been evaporated, is inside the loading chamber 200.

At this time, as explained hereinabove, the vacuum deposition chamber 20, the outer enclosure 11 that is in direct communication with the vacuum deposition chamber 20, and the evaporation chamber 100 are at a substantially identical pressure, close to a vacuum level, comprised between 10⁻³ and 10⁻⁸ Torr.

The first crucible 110, that is engaged with the evaporation chamber 100 of the evaporation cell 10, allows, thanks to its joint 117, to isolate the loading chamber 200 with respect to the adjacent evaporation chamber 100 and to the vacuum deposition chamber 20.

It is hence possible to reaerate the loading chamber 200 without impacting the vacuum of the vacuum deposition chamber 20.

Hence, in a loading step of the method, the trap door 201 of the loading chamber 200 is open to remove the previously emptied crucible 130. The pressure in the loading chamber 200 is then substantially higher than that inside the vacuum deposition chamber 20, typically close to 1 atmosphere.

The second crucible 120 is then introduced, from the outside of the evaporation cell 10, possibly from a lock chamber, generally called “glove box”, under a neutral atmosphere, inside the loading chamber 200 through the trap door 201, and this second crucible 120 is deposited on the carrousel 211 of the loading chamber 200.

After the step of introduction of the second crucible 120 in the loading chamber 200, a step of confining this latter is performed.

The confinement step is intended to bring back the pressure inside the loading chamber 200 to a level comparable to that of the evaporation chamber 100 during the evaporation of the first crucible 110, i.e. about 10⁻³ to 10⁻⁸ Torr.

During this confinement step, the trap door 201 of the loading chamber is then tightly closed with respect to the outside of the evaporation cell 10, and thanks to the additional pump 222, the inside of the loading chamber 200 is pumped so as to reach the above-mentioned level of pressure.

The levels of pressure in the loading chamber 200 and in the evaporation chamber 100 are then comparable, so that the plate 212 supporting the first crucible 110 can be remove with no significant effort and with no risk of breakage.

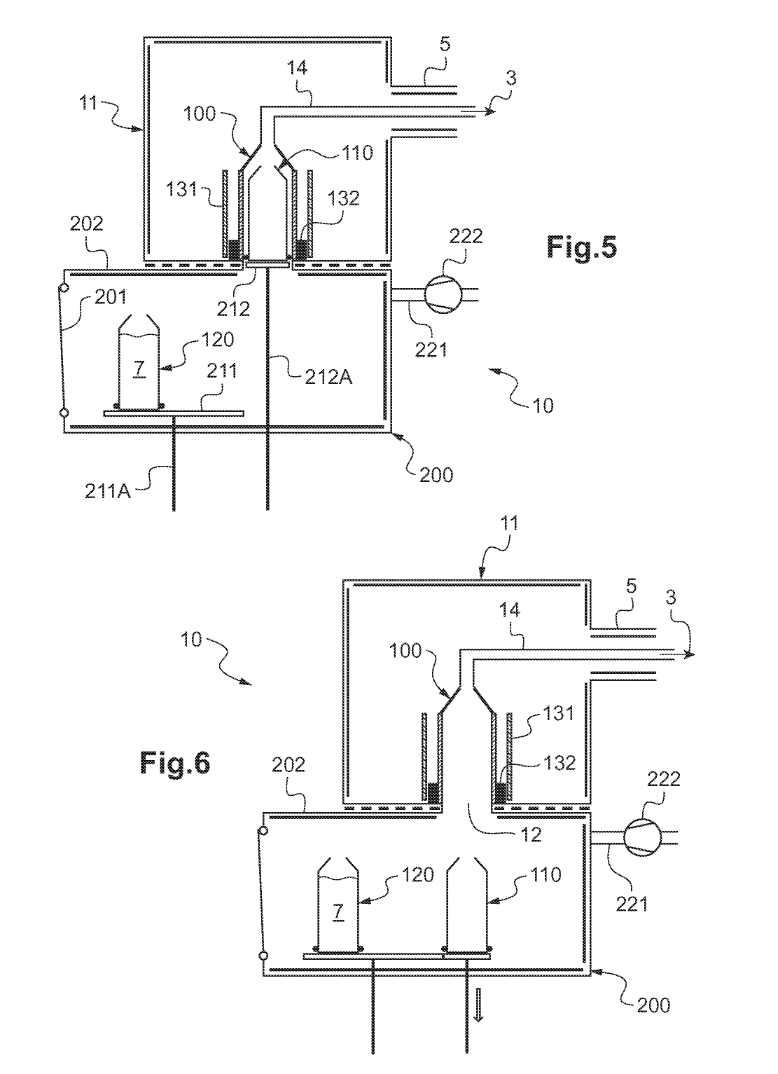

During the loading and confinement steps, it is understood that the flow of vapor 116 generated by the first crucible 110 heated by the electric resistances 131 and the thermal shield 132 is not stopped and hence that the level of the material 7 in the first crucible 110 lowers (cases of FIGS. 3 and 4) until the first crucible 110 is empty (case of FIG. 5) or until the level of material 7 in the first crucible 110 is lower than a predetermined minimal threshold.

The first crucible 110 can then be disengaged from the evaporation chamber 100 thanks to the actuation of the piston 212A downwards, which allows the first crucible 110 to be transferred from the evaporation chamber 100 towards the loading chamber 200.

In other words, during the disengagement step, the first crucible 110 is removed from the evaporation chamber 100 by being passed through the insertion opening 12 of the evaporation cell 10, which places the loading chamber 200 in communication with the evaporation chamber 100.

The situation is then that shown in FIG. 6, where the first crucible 110, empty, rests on the plate 212 is bottom position, and where the second crucible 120, full, is on the loading carrousel 211.

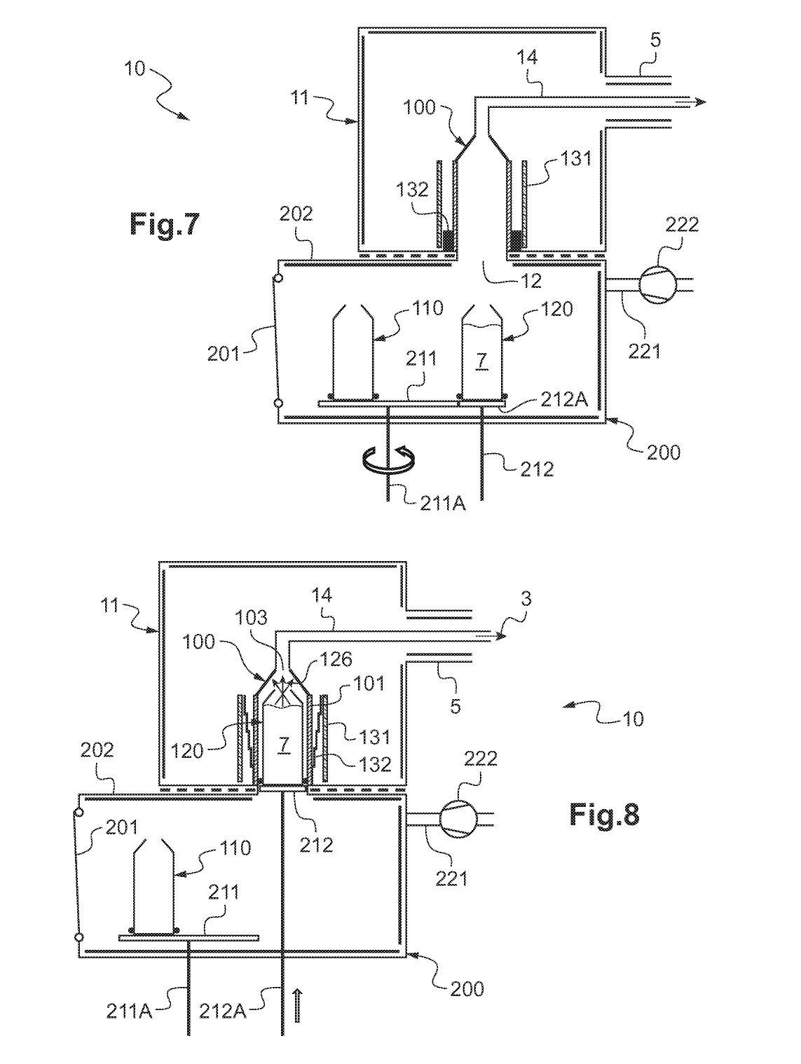

By rotation of the carrousel 211 (see FIG. 7), it is then possible to invert the first crucible 110 with the second crucible 120, so that the latter is positioned on the plate 212 of the loading chamber 200.

The second crucible 120 can then be engaged with the evaporation chamber 100 by actuation of the piston 212A upward.

The second crucible 120 is then inserted into the evaporation chamber 100 through the insertion opening 12 (see FIG. 8).

It will be noted herein that, thanks to the joint 127 attached to the body 121 of the second crucible 120, the step of engaging the second crucible allows to tightly shut the insertion opening 12, so that the engagement step leads to the isolation of the loading chamber 200 with respect to the evaporation chamber 100 of the evaporation cell, and also to the vacuum deposition chamber 20 of the vacuum deposition apparatus 1.

As explained hereinabove for the first crucible 110, once the isolation provided by the engagement of the second crucible 120, it is then possible to unload the first crucible 110 from the loading chamber 200, for example to introduce one or several new full crucibles, for the reloading of the evaporation cell 20.

Once engaged with the evaporation chamber 100 (cf. FIG. 8), the second crucible 120 can be placed in conditions of evaporation thanks to the evaporation means, to generate a flow of vapor 126 of the material through the outlet of the evaporation chamber 100.

It is hence understood that the reloading method according to the invention allows to reduce the time during which the flow of vapor of the material is interrupted.

Indeed, this interruption is limited in time by the operations of disengaging the first crucible 110 and engaging the second crucible 120 and placing it in conditions of evaporation. The crucibles 110, 120 being of small volume, their placement in conditions of evaporation may be rapid as the quantity of material 7 to be heated is limited.

That way, it can be considered that the method for reloading the evaporation cell 10 according to the invention allows the vacuum deposition apparatus 1 to operate in a quasi-continuous regime of production.

Advantageously, it is moreover possible, before the engagement of the second crucible 120 with the evaporation chamber 100, to prepare the second crucible 120 then placed in the loading chamber 200 so as to still further reduce the duration of interruption of the flow of vapor.

This preparation step is intended to reduce the duration of the step of placement in conditions of evaporation of the second crucible 120.

More particularly, herein, it is hence performed, thanks to the heating means 206 of the loading chamber 200, a pre-heating of the second crucible 120 up to a predetermined pre-heating temperature.

Preferably, the power of the heating means is adjusted so that the pre-heating temperature be lower than the temperature of evaporation of the material 7 contained in the second crucible 120 so as to prevent the beginning of evaporation of said material 7.

Although the reloading method according to the invention has been described with only a single crucible waiting in the loading chamber, it can easily be implemented with several crucibles.

For example, during the reloading step, it is possible to introduce as many crucibles as the carrousel can receive. In this case, the opening of the trap door of the loading chamber and the use of the additional pump are less frequent and the conditions of temperature and pressure in the loading chamber are more stable. At each change of an empty crucible, one of the full crucibles remaining on the carrousel is inserted. When all the crucibles present on the carrousel are empty (a crucible being in course of evaporation in the evaporation chamber)

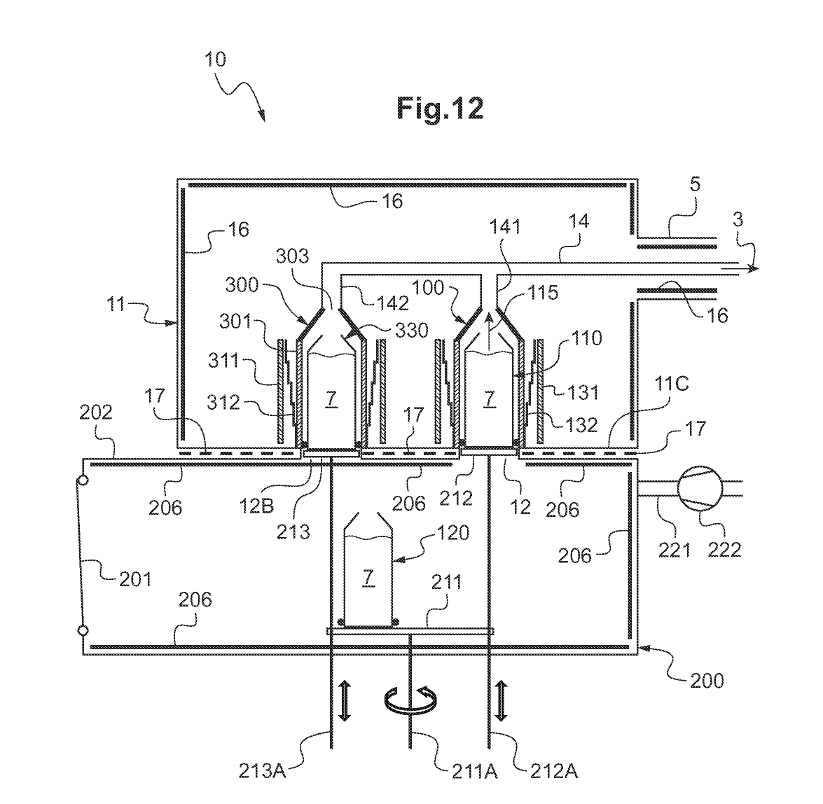

Moreover, as shown in FIG. 12, the reloading method according to the invention can be implemented for a vacuum deposition apparatus 1 with an evaporation cell 10 having two evaporation chambers 100, 300.

It will be understood from the following description that a continuous production of vapor of material by the evaporation cell is possible.

In the example described herein, these two evaporation chambers 100, 300 are identical to the above-described evaporation chamber 100 (cf. FIGS. 2 to 11) and the respective evaporation means 131, 132, 311, 312 are also identical. The evaporation chambers 100, 300 are mounted in parallel on the injection duct 14, respectively thanks to duct portions 141, 142 connected on the outlets 103, 303 of said evaporation chambers 100, 300.

Between the two evaporation chambers 100, 300 are arranged in the evaporation cell 10 thermal shields made of a refractory material such as aluminum, so as to make these two evaporation chambers 100, 300 thermally independent from each other.

The outer enclosure 11 of the evaporation cell 10 includes two insertion openings 12, 12B allowing the engagement and disengagement of the crucibles.

Correspondingly, the confining enclosure 202 of the loading chamber 200 comprises on its upper wall two openings located opposite these insertion openings 12, 12B, so that the loading chamber 200 is in communication with the first evaporation chamber 100 and the second loading chamber 300, respectively, through the first insertion opening 12 and the second insertion opening 12B, when these latter are not shut.

Moreover, the loading chamber 200 includes, in addition to the carrousel 211 and to the first plate 212, a second plate 213 associated with its piston 213A, which allows the disengagement and the insertion of a crucible in the second evaporation chamber 300. The carrousel 211 is arranged in the loading chamber 200 so as to be able to deposit a crucible on either one of the plates 212, 213.

The reloading method according to the invention and the way the latter allows a continuous production will now be described.

It is considered herein that the initial situation of the evaporation cell is that shown in FIG. 12:
a first crucible 110, almost empty, placed in the first evaporation chamber 100, is under evaporation and generates a flow of vapor 116 of material 7 through the outlet 103, which flow of vapor 116 being then led to the injector 13 (not shown) through the duct portion 141 and to the injection duct 14.
a second crucible 120, full, placed in the loading chamber 200 that is vacuumed using the additional pump 222, is waiting on the carrousel 211 and pre-heated by the heating means 206 of the loading chamber 200;
a third crucible 330, full, engaged with the second evaporation chamber 300, is progressively placed in conditions of evaporation thanks to the electric resistances 311 heating the third crucible 330 through the thermal shield 312 and the body 301 of the evaporation chamber 300.

Advantageously, it is provided that the third crucible 330 engaged with the second evaporation chamber 300 begins its evaporation when the quantity of material 7 to be evaporated remaining in the first crucible 110 is lower than a predetermined minimum threshold, so as to maintain a constant flow rate for the flow of material led within the injection duct 14 to the injector 13.

It can also be provided to mount tight valves of the “all or nothing” type and/or regulation valves on the portions 141, 142 of the injection duct 13, either to control the flow of vapor inside the injection duct, or to prevent the flow of vapor exiting from one of the evaporation chambers to pollute the other evaporation chamber.

When the first crucible 110 is empty or when the quantity of material 7 to be evaporated remaining in the first crucible 110 is lower than a predetermined lower limit (this lower limit being lower than the previous minimum threshold), it is replaced by the reloading of the evaporation cell 10. At this time, the second evaporation chamber 300 takes over, the flow of vapor generated by the third crucible 330 being directed to the injector 13, so that the flow rate of vapor injected in the vacuum deposition chamber 20 is not interrupted.

During this reloading, the first crucible 110 is disengaged from the first evaporation chamber 100 by being passed through the first insertion opening 12 using the plate 212.

Then, the first crucible 110 is unloaded from the plate 212 onto the carrousel 211 and the second crucible 120 of the carrousel 211 is loaded onto the plate 212.

The second crucible 120 is then engaged with the first evaporation chamber 100 and it is progressively placed in conditions of evaporation so that, when the quantity of material 7 to be evaporated remaining in the third crucible 110, which is in course of evaporation in the second evaporation chamber 300, in lower that the predetermined minimum threshold.

Once the second crucible 120 engaged with the first evaporation chamber 100, the loading chamber 200 is isolated from the two evaporation chambers 100, 300 and also from the vacuum deposition chamber 20.

It is then time to open the trap door 201 of the loading chamber 200 to remove the first crucible 110 and to introduce a fourth crucible (not shown) in the reaerated loading chamber 200, the pressure in the loading chamber 200 being then substantially higher than that in the vacuum deposition chamber 20.

Finally, it can be proceeded to the step of confining the loading chamber 200 to bring back the pressure inside this loading chamber 200 to a level comparable to that of the evaporation chambers 100, 300.

When the third crucible 330 becomes empty, it can be implemented, according to the reloading method according to the invention, the steps of disengaging the third crucible 330, and of engaging and placing in conditions of evaporation the fourth crucible engaged with the second evaporation chamber 300.

Hence, by implementing the reloading method according to the invention with an evaporation cell including at least two evaporation chambers and a loading chamber adjacent to said evaporation chambers, it is possible to never interrupt the flow of vapor of material transported up to the injector to be injected into the vacuum deposition chamber of the vacuum deposition apparatus. It is hence possible to provide a continuous production, with a streaming of substrates opposite said injector.

In order to limit the reloading rate of the evaporation cell, it can advantageously be provided in the outer enclosure of the evaporation cell a barrel including a great number of evaporation chambers, each provided with its own evaporation means and possibly its own system of valves at the exit of said chambers.

This barrel can be loaded in only one times by means of a “loader” gathering together a number of crucibles corresponding to the number of evaporation chambers, the providing of the loader allowing to engage simultaneously all the crucibles in their respective evaporation chamber.

The reloading method of the evaporation cell then comprises:
a step of loading a second loader, gathering a plurality of crucibles each containing the material to be evaporated, into a loading chamber previously isolated from said evaporation chambers adjacent to the barrel, the pressure in said loading chamber being then substantially higher than that inside the vacuum deposition chamber,
after said introduction step, a step of confining said loading chamber intended to bring back the pressure inside said loading chamber to a level comparable to that in the evaporation chambers of the barrel,
after said confinement step, a step of disengaging said first loading from said barrel during which said first loader is transferred from said barrel towards said loading chamber,
after said step of disengaging the first loader, a step of engaging said second loader with said barrel of evaporation chambers, and
after said step of engaging said second crucible, a step of placing said crucibles of the second loader in conditions of evaporation.

1. A method for reloading an evaporation cell (10) intended to evaporate a material (7), in order for the latter to be deposited onto a substrate (2) placed in a vacuum deposition chamber (20), a first crucible (110) containing said material (7) to be evaporated being engaged with an evaporation chamber (100) of said evaporation cell (10), evaporation means (101, 131, 132) being provided to place said first crucible (110) in conditions of evaporation to generate a flow of vapor (116) of the material (7) through an outlet (103) of said evaporation chamber (100), said outlet (103) being connected to an injector (13) for the injection of said vapor into said vacuum deposition chamber (20),
said reloading method including:
a step of loading a second crucible (120) containing the material (7) to be evaporated into a loading chamber (200) previously isolated from said adjacent evaporation chamber (100), the pressure inside said loading chamber (200) being then substantially higher than that inside the vacuum deposition chamber (20),
after said step of introduction, a step of confining said loading chamber (200) intended to bring back the pressure inside said loading chamber (200) to a level comparable to that of said evaporation chamber (100) during the evaporation of said first crucible (110),
after said confinement step, a step of disengaging said first crucible (110) from said evaporation chamber (100), during which said first crucible (110) is transferred from said evaporation chamber (100) to said loading chamber (200),
after said step of disengaging the first crucible (110), a step of engaging said second crucible (120) with said evaporation chamber (100), and
after said step of engaging said second crucible (120), a step of placing said second crucible (120) in conditions of evaporation to generate a flow of vapor (126) of the material (7) through said outlet (103) of the evaporation chamber (100),
characterized in that, during said step of engaging said second crucible (120), said loading chamber (200) is isolated from said evaporation chamber (100) and from said vacuum deposition chamber (20).

2. The reloading method according to claim 1, wherein, during said step of loading said second crucible (120), a trap door (201) of said loading chamber (200) is open, and said second crucible (120) is introduced into said loading chamber (200), from the outside of said evaporation cell (10), through said trap door (201).

3. The reloading method according to claim 2, wherein, during said confinement step, the trap door (201) is tightly closed with respect to the outside of said evaporation cell (10), and a pumping is performed inside said loading chamber (200).

4. The reloading method according to claim 1, wherein:
during said step of disengaging the first crucible (110), said first crucible (110) is removed from said evaporation chamber (100) by being passed through an insertion opening (12) placing said loading chamber (200) in communication with said evaporation chamber (100), and
during said step of engaging said second crucible (120), said second crucible (120) is inserted into said evaporation chamber (100) by being passed through said insertion opening (12), and said insertion opening (12) is tightly shut to isolate said loading chamber (200) of said evaporation chamber (100).

5. The reloading method according to claim 1,
including, before said step of engaging said second crucible (120) with said evaporation chamber (100), a step of preparing said second crucible (120) in said loading chamber (200) intended to reduce the duration of said step of placing said second crucible (120) in conditions of evaporation.

6. The reloading method according to claim 5, wherein said preparation step comprises a step of pre-heating said second crucible (120) in said loading chamber (200), up to a predetermined pre-heating temperature.

7. The reloading method according to claim 2, wherein:
during said step of disengaging the first crucible (110), said first crucible (110) is removed from said evaporation chamber (100) by being passed through an insertion opening (12) placing said loading chamber (200) in communication with said evaporation chamber (100), and
during said step of engaging said second crucible (120), said second crucible (120) is inserted into said evaporation chamber (100) by being passed through said insertion opening (12), and said insertion opening (12) is tightly shut to isolate said loading chamber (200) of said evaporation chamber (100).

8. The reloading method according to claim 3, wherein:
during said step of disengaging the first crucible (110), said first crucible (110) is removed from said evaporation chamber (100) by being passed through an insertion opening (12) placing said loading chamber (200) in communication with said evaporation chamber (100), and
during said step of engaging said second crucible (120), said second crucible (120) is inserted into said evaporation chamber (100) by being passed through said insertion opening (12), and said insertion opening (12) is tightly shut to isolate said loading chamber (200) of said evaporation chamber (100).
